(19) United States
(12) Patent Application Publication
(10) Pub. No.: US 2026/0047150 A1
(43) Pub. Date: Feb. 12, 2026

(54) TRANSISTOR AND METHOD FOR MANUFACTURING SAME

(71) Applicant: Microchip Technology Incorporated, Chandler, AZ (US)

(72) Inventor: Shesh Mani Pandey, Bentonville, AR (US)

(73) Assignee: Microchip Technology Incorporated, Chandler, AZ (US)

(21) Appl. No.: 19/041,027

(22) Filed: Jan. 30, 2025

Related U.S. Application Data
(60) Provisional application No. 63/681,286, filed on Aug. 9, 2024.

(51) Int. Cl. H10D 30/83; H10D 30/01; H10D 62/60

(52) U.S. Cl. CPC H10D 30/832; H10D 30/051; H10D 62/60

(57) ABSTRACT

A transistor comprising an epi layer formed within a substrate. A junction field-effect transistor implant layer formed into the epi layer. A well implant layer formed within the junction field-effect transistor implant layer. A source implant layer formed into the junction field-effect transistor implant layer. A plurality of first gate implant layers formed into the junction field-effect transistor implant layer. A plurality of first gate contacts operatively connected to the respective first gate implant layer. A source contact operatively connected to the source implant layer. A second gate contact operatively connected to the well implant layer.

### CROSS-REFERENCE TO RELATED APPLICATION

The present application claims priority to U.S. Provisional Patent Application No. 63/681,286 filed on Aug. 9, 2024, the contents of which are hereby incorporated by reference in their entirety.

### TECHNICAL FIELD

The present disclosure relates generally to transistors, and more specifically to Junction Field Effect Transistors and methods for manufacturing same to improve the performance of the transistor.

### SUMMARY

According to an aspect of one or more examples, there is provided a transistor that may include a substrate, an epi layer formed within the substrate, a junction field effect transistor implant layer formed into the epi layer, a well implant layer formed within the junction field effect transistor implant layer, a source implant layer formed into the junction field effect transistor implant layer, a plurality of first gate implant layers formed into the junction field effect transistor implant layer, a plurality of first gate contacts operatively connected to the respective first gate implant layer, a source contact operatively connected to the source implant layer, and a second gate contact operatively connected to the well implant layer. The plurality of first gate implant layers may be operatively connected to the source implant layer and the plurality of first gate contacts may be operatively connected to the source contact. The substrate may comprise a first concentration of a first type dopant. The epi layer may comprise a second concentration of the first type dopant, the first concentration may be greater than the second concentration. The junction field effect transistor layer may comprise a third concentration of the first type dopant. The well implant layer may comprise a fourth concentration of a second type dopant. The source implant layer may comprise a fifth concentration of the first type dopant. The plurality of first gate implant layers may comprise a sixth concentration of the second type dopant. The first type dopant may comprise an n-type dopant and the second type dopant may comprise a p-type dopant. The first type dopant may comprise a p-type dopant and the second type dopant may comprise an n-type dopant.

According to an aspect of one or more examples, there is provided method of manufacturing a transistor. The method may include providing a substrate, forming an epi layer within the substrate, implanting a junction field effect transistor implant layer into the epi layer, implanting a well implant layer into the junction field effect transistor implant layer, implanting a source implant layer into the junction field effect transistor implant layer, implanting a plurality of first gate implant layers into the junction field effect transistor implant layer, forming a plurality of first gate contacts operatively connected to the respective first gate implant layer, forming a source contact operatively connected to the source implant layer, and forming a second gate contact operatively connected to the well implant layer. The plurality of first gate implant layers may be operatively connected to the source implant layer and the plurality of first gate contacts may be operatively connected to the source contact. The substrate may comprise a first concentration of a first type dopant. The epi layer may comprise a second concentration of the first type dopant, the first concentration may be greater than the second concentration. The junction field effect transistor layer may comprise a third concentration of the first type dopant. The well implant layer may comprise a fourth concentration of a second type dopant. The source implant layer may comprise a fifth concentration of the first type dopant. The plurality of first gate implant layers may comprise a sixth concentration of the second type dopant. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1A is a cross sectional view of a transistor according to one or more examples.

FIG. 1B is a top view of a transistor according to one or more examples.

FIG. 2A is a cross sectional view of a transistor according to one or more examples.

FIG. 2B is a top view of a transistor according to one or more examples.

FIG. 3A is a cross sectional view of some of the steps in a method of manufacturing a transistor according to one or more examples.

FIG. 3B is a cross sectional view of some of the steps in a method of manufacturing a transistor according to one or more examples.

FIG. 3C is a cross sectional view of some of the steps in a method of manufacturing a transistor according to one or more examples.

FIG. 3D is a cross sectional view of some of the steps in a method of manufacturing a transistor according to one or more examples.

FIG. 3E is a cross sectional view of some of the steps in a method of manufacturing a transistor according to one or more examples.

FIG. 4A is a cross sectional view of some of the steps in a method of manufacturing a transistor according to one or more examples.

FIG. 4B is a cross sectional view of some of the steps in a method of manufacturing a transistor according to one or more examples.

FIG. 4C is a cross sectional view of some of the steps in a method of manufacturing a transistor according to one or more examples.

FIG. 4D is a cross sectional view of some of the steps in a method of manufacturing a transistor according to one or more examples.

FIG. 4E is a cross sectional view of some of the steps in a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

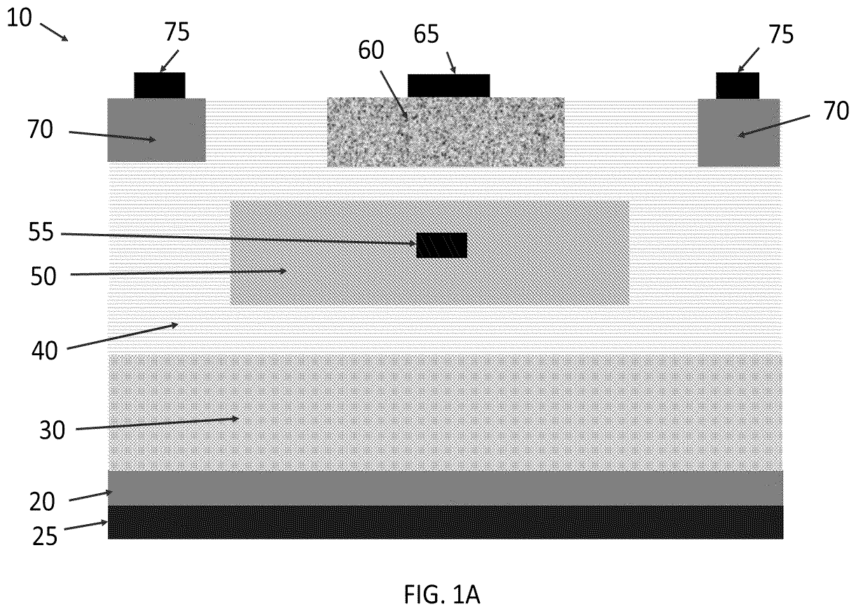

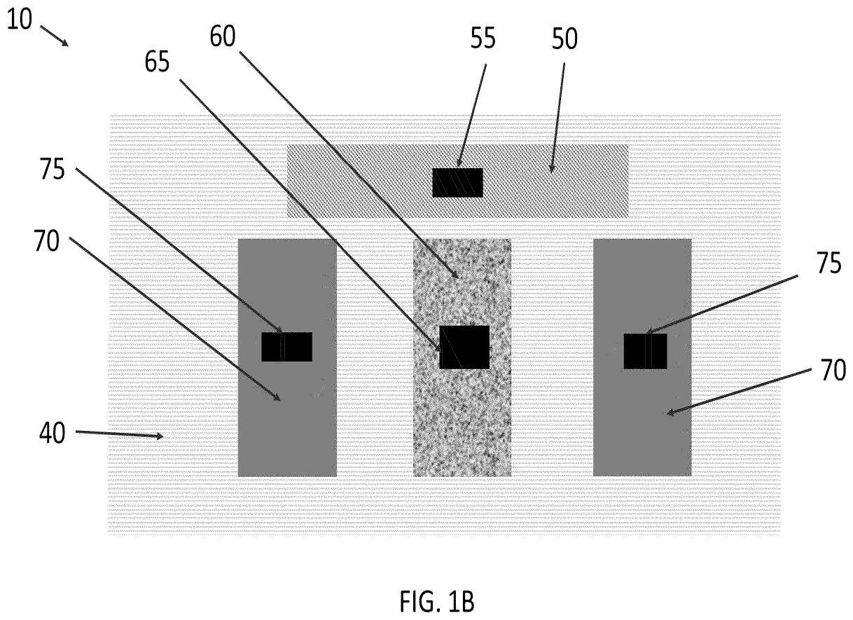

FIG. 1A show a cross sectional view of a transistor 10 according to one or more examples. Transistor 10 may represent, and may be called a junction field effect transistor, without limitation. The example transistor 10 (junction field effect transistor) of FIG. 1A includes a substrate 20. The substrate 20 shown in FIG. 1A may have a first concentration of a first type dopant, e.g., 5E18 (i.e. 5×10¹⁸). A drain contact 25 may be formed at a first side of the substrate 20. The example transistor 10 (junction field effect transistor) of FIG. 1A may include an epi layer 30 formed within the substrate 20 at a second side of the substrate 20. The second side of the substrate 20 is opposite the first side of the substrate 20 where the drain contact 25 was formed. The epi layer 30 may comprise a second concentration of the first type dopant, wherein the first concentration of first type dopant in the substrate 20 may be greater than the second concentration of first type dopant in the epi layer 30. The example transistor 10 (junction field effect transistor) of FIG. 1A may include a junction field effect transistor implant layer 40 formed into the epi layer 30. The junction field effect transistor layer 40 may comprise a third concentration of the first type dopant. The example transistor 10 (junction field effect transistor) of FIG. 1A may include a well implant layer 50 formed into the junction field effect transistor implant layer 40. The well implant layer 50 may comprise a fourth concentration of a second type dopant that may have a peak doping in the range 1E17 to 5E18. The example transistor 10 (junction field effect transistor) of FIG. 1A may include a source implant layer 60 formed into the junction field effect transistor implant layer 40. The source implant layer 60 may comprise a fifth concentration of the first type dopant. The example transistor 10 (junction field effect transistor) of FIG. 1A may include a plurality of first gate implant layers 70 formed into the junction field effect transistor implant layer 40. The plurality of first gate implant layers 70 may comprise a sixth concentration of the second type dopant. The example transistor 10 (junction field effect transistor) of FIG. 1A may include a plurality of first gate contacts 75 operatively connected to the respective first gate implant layer 70 of the plurality of first gate implant layers 70. The plurality of first gate contacts 75 may be made from a metal, polysilicon, or other suitable material. The example transistor 10 (junction field effect transistor) of FIG. 1A may include a source contact 65 operatively connected to the source implant layer 60. The source contact 65 may be made from a metal, polysilicon, or other suitable material. The example transistor 10 (junction field effect transistor) of FIG. 1A may include a second gate contact 55 operatively connected to the well implant layer 50. The second gate contact 55 may be made from a metal, polysilicon, or other suitable material. When a gate-to-source voltage is applied to the transistor 10 (junction field effect transistor) of FIG. 1A, current flows through a channel created around the well implant layer 50 from the source contact 65 to the drain contact 25.

In one example of the example transistor 10 (junction field effect transistor) of FIG. 1A, the first type dopant may be an n-type dopant and the second type dopant may be a p-type dopant. In another example of the example transistor 10 (junction field effect transistor) of FIG. 1A, the first type dopant may be a p-type dopant and the second type dopant may be an n-type dopant.

FIG. 1B show a top view of a transistor 10 according to one or more examples. Transistor 10 may represent, and may be called a junction field effect transistor, without limitation. The example transistor 10 (junction field effect transistor) of FIG. 1B may include a junction field effect transistor implant layer 40. The example transistor 10 (junction field effect transistor) of FIG. 1B may include a well implant layer 50 formed into the junction field effect transistor implant layer 40. The example transistor 10 (junction field effect transistor) of FIG. 1B may include a source implant layer 60 formed into the junction field effect transistor implant layer 40. The example transistor 10 (junction field effect transistor) of FIG. 1B may include a plurality of first gate implant layers 70 formed into the junction field effect transistor implant layer 40. The example transistor 10 (junction field effect transistor) of FIG. 1B may include a plurality of first gate contacts 75 operatively connected to the respective first gate implant layer 70 of the plurality of first gate implant layers 70. The plurality of first gate contacts 75 may be made from a metal, polysilicon, or other suitable material. The example transistor 10 (junction field effect transistor) of FIG. 1B may include a source contact 65 operatively connected to the source implant layer 60. The source contact 65 may be made from a metal, polysilicon, or other suitable material. The example transistor 10 (junction field effect transistor) of FIG. 1B may include a second gate contact 55 operatively connected to the well implant layer 50. The second gate contact 55 may be made from a metal, polysilicon, or other suitable material. When a gate-to-source voltage is applied to the transistor 10 (junction field effect transistor) of FIG. 1B, current flows through a channel created around the well implant layer 50 from the source contact 65 to the drain contact 25.

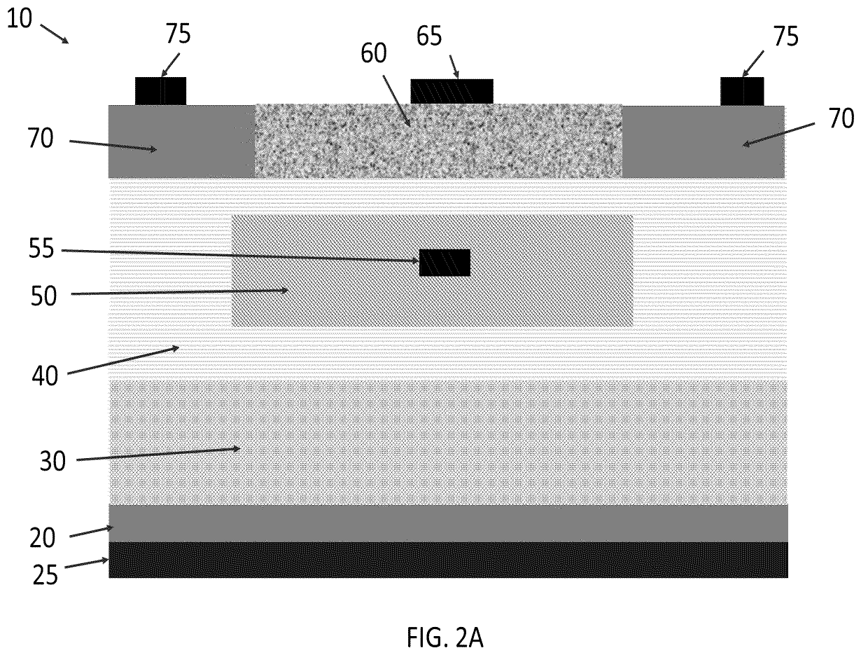

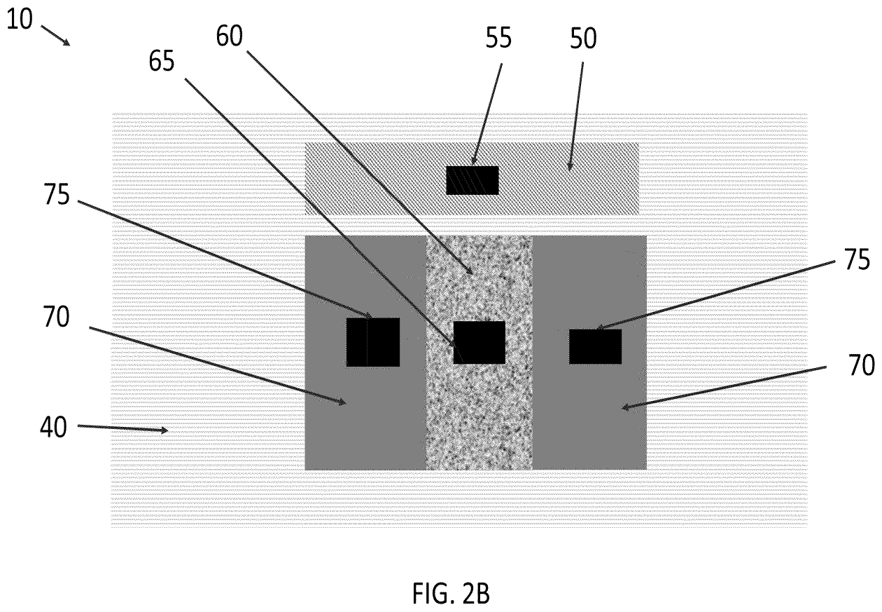

FIG. 2A show a cross sectional view of a transistor 10 according to one or more examples. Transistor 10 may represent, and may be called a junction field effect transistor, without limitation. The example transistor 10 (junction field effect transistor) of FIG. 2A include a substrate 20. The substrate 20 shown in FIG. 2A may have a first concentration of a first type dopant, e.g., 5E18 (i.e. 5×10¹⁸). A drain contact 25 may be formed at a first side of the substrate 20. The example transistor 10 (junction field effect transistor) of FIG. 2A may include an epi layer 30 formed within the substrate 20 at a second side of the substrate 20. The second side of the substrate 20 is opposite the first side of the substrate 20 where the drain contact 25 was formed. The epi layer 30 may comprise a second concentration of the first type dopant, wherein the first concentration of first type dopant in the substrate 20 may be greater than the second concentration of first type dopant in the epi layer 30. The example transistor 10 (junction field effect transistor) of FIG. 2A may include a junction field effect transistor implant layer 40 formed into the epi layer 30. The junction field effect transistor layer 40 may comprise a third concentration of the first type dopant. The example transistor 10 (junction field effect transistor) of FIG. 2A may include a well implant layer 50 formed into the junction field effect transistor implant layer 40. The well implant layer 50 may comprise a fourth concentration of a second type dopant that may have a peak doping in the range 1E17 to 5E18. The example transistor 10 (junction field effect transistor) of FIG. 2A may include a source implant layer 60 formed into the junction field effect transistor implant layer 40. The source implant layer 60 may comprise a fifth concentration of the first type dopant. The example transistor 10 (junction field effect transistor) of FIG. 2A may include plurality of first gate implant layers 70 formed into the junction field effect transistor implant layer 40. The plurality of first gate implant layers 70 may comprise a sixth concentration of the second type dopant. The example transistor 10 (junction field effect transistor) of FIG. 2A may include a plurality of first gate contacts 75 operatively connected to the respective first gate implant layer 70 of the plurality of first gate implant layers 70. The plurality of first gate contacts 75 may be made from a metal, polysilicon, or other suitable material. The example transistor 10 (junction field effect transistor) of FIG. 2A may include a source contact 65 operatively connected to the source implant layer 60. The plurality of gate implant layers 70 may be operatively connected to the source implant layer 60. The plurality of first gate contacts 75 may be operatively connected to the source contact 65. The source contact 65 may be made from a metal, polysilicon, or other suitable material. The example transistor 10 (junction field effect transistor) of FIG. 2A may include a second gate contact 55 operatively connected to the well implant layer 50. The second gate contact 55 may be made from a metal, polysilicon, or other suitable material. When a gate-to-source voltage is applied to the transistor (junction field effect transistor) of FIG. 2A, current flows through a channel created around the well implant layer 50 from the source contact 65 to the drain contact 25.

In one example of the example transistor 10 (junction field effect transistor) of FIG. 2A, the first type dopant may be an n-type dopant and the second type dopant may be a p-type dopant. In another example of the example transistor 10 (junction field effect transistor) of FIG. 2A, the first type dopant may be a p-type dopant and the second type dopant may be an n-type dopant.

FIG. 2B show a top view of a transistor 10 according to one or more examples. Transistor 10 may represent, and may be called a junction field effect transistor, without limitation. The example transistor 10 (junction field effect transistor) of FIG. 2B may include a junction field effect transistor implant layer 40. The example transistor 10 (junction field effect transistor) of FIG. 2B may include a well implant layer 50 formed into the junction field effect transistor implant layer 40. The example transistor 10 (junction field effect transistor) of FIG. 2B may include a source implant layer 60 formed into the junction field effect transistor implant layer 40. The example transistor 10 (junction field effect transistor) of FIG. 2B may include plurality of first gate implant layers 70 formed into the junction field effect transistor implant layer 40. The example transistor 10 (junction field effect transistor) of FIG. 2B may include a plurality of first gate contacts 75 operatively connected to the respective first gate implant layer 70 of the plurality of first gate implant layers 70. The plurality of first gate contacts 75 may be made from a metal, polysilicon, or other suitable material. The example transistor 10 (junction field effect transistor) of FIG. 2B may include a source contact 65 operatively connected to the source implant layer 60. The plurality of gate implant layers 70 may be operatively connected to the source implant layer 60. The plurality of first gate contacts 75 may be operatively connected to the source contact 65. The source contact 65 may be made from a metal, polysilicon, or other suitable material. The example transistor 10 (junction field effect transistor) of FIG. 2B may include a second gate contact 55 operatively connected to the well implant layer 50. The second gate contact 55 may be made from a metal, polysilicon, or other suitable material. When a gate-to-source voltage is applied to the transistor (junction field effect transistor) of FIG. 2B, current flows through a channel created around the well implant layer 50 from the source contact 65 to the drain contact 25.

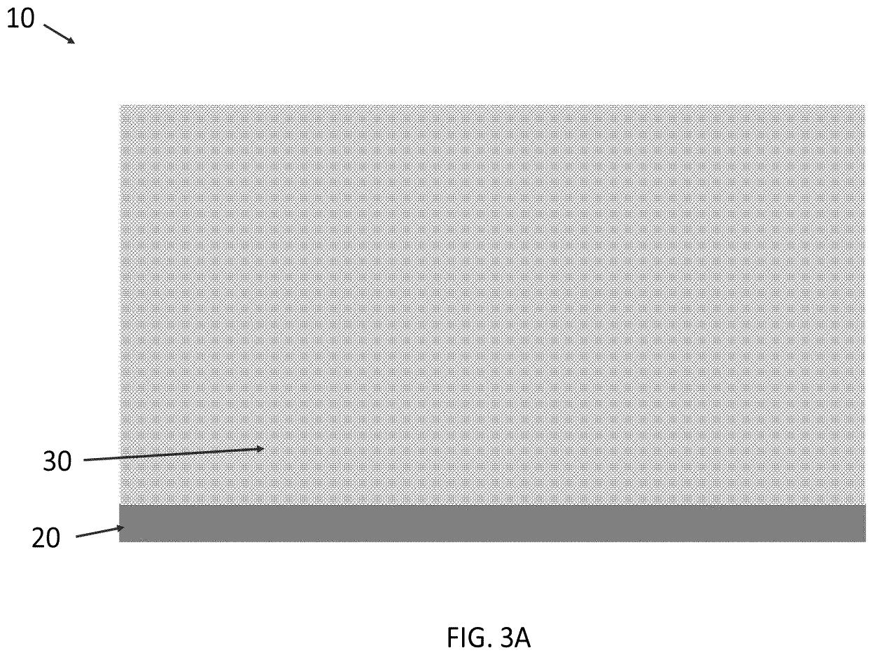

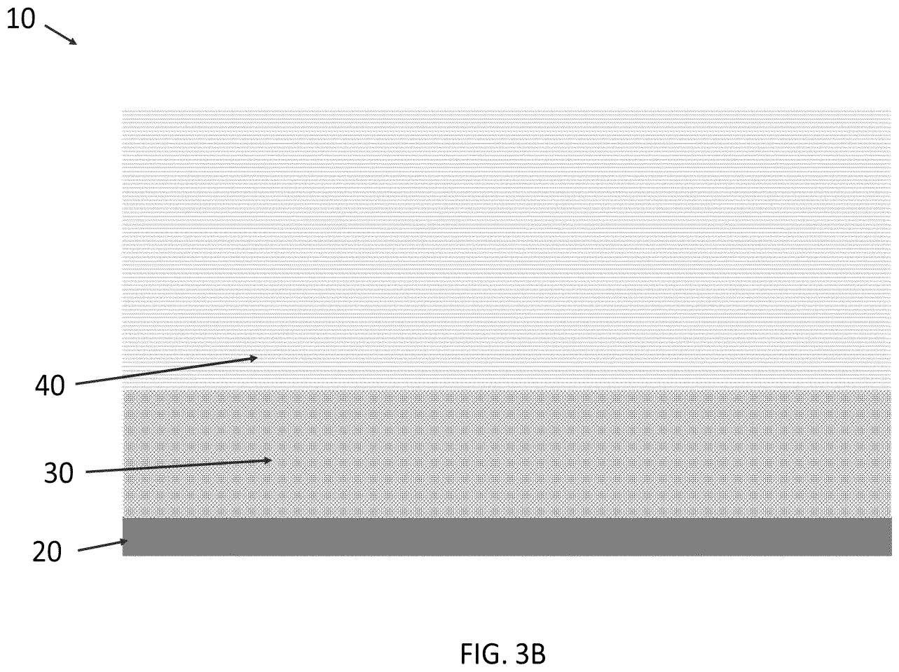

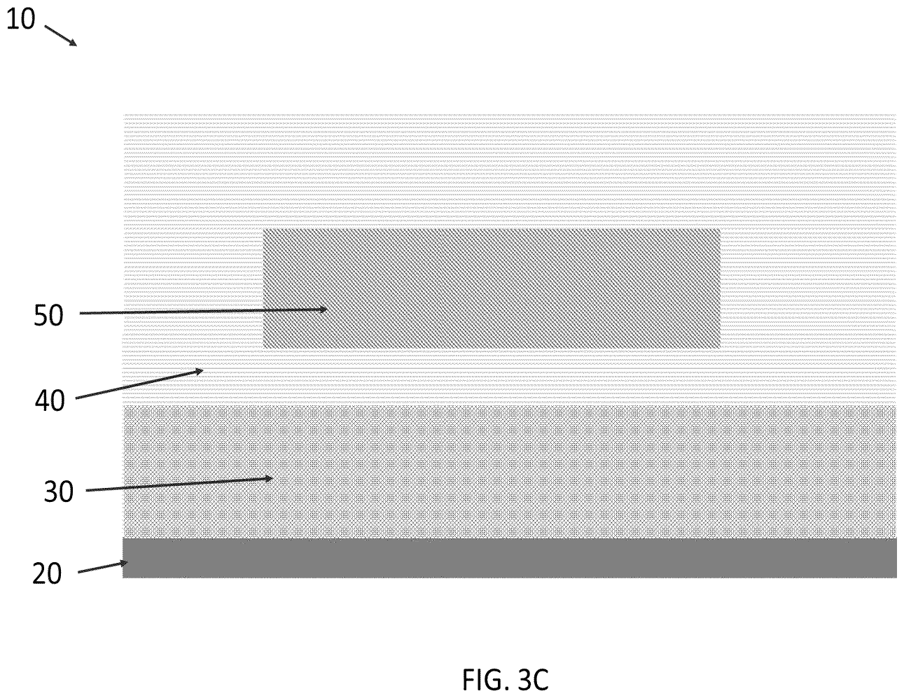

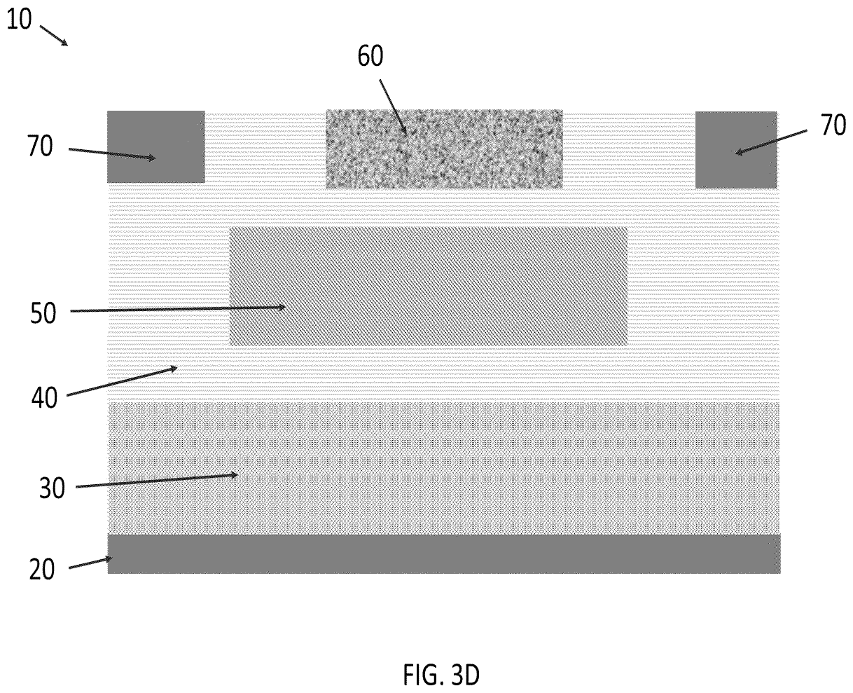

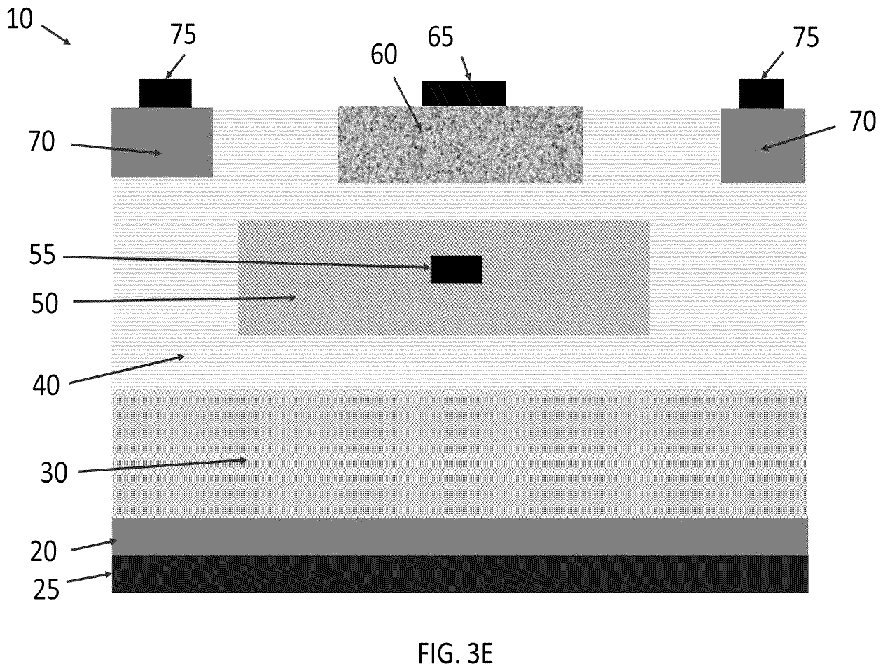

FIGS. 3A-3E show a method of manufacturing transistor 10 according to one or more examples. Although the example method shown in FIGS. 3A-3E include steps shown in a particular order, the steps may be performed in a different order, and may include additional steps that are not explicitly shown.

FIG. 3A is a cross sectional view of some of the steps in a method of manufacturing a transistor 10 according to one or more examples. Transistor 10 may represent, and may be called a junction field effect transistor, without limitation. In FIG. 3A, the example method shows a substrate 20 that may have a first concentration of a first type dopant, e.g., 5E18 (i.e. 5×10¹⁸). In FIG. 3A, the method may include forming an epi layer 30 within the substrate 20. The epi layer 30 may comprise a second concentration of the first type dopant, wherein the first concentration of first type dopant in the substrate 20 may be greater than the second concentration of first type dopant in the epi layer 30.

FIG. 3B is a cross sectional view of some of the steps in a method of manufacturing a transistor 10 according to one or more examples. In FIG. 3B, the method may include implanting a junction field effect transistor layer 40 into the epi layer 30. The junction field effect transistor layer 40 may comprise a third concentration of the first type dopant.

FIG. 3C is a cross sectional view of some of the steps in a method of manufacturing a transistor 10 according to one or more examples. In FIG. 3C, the method may include implanting a well implant layer 50 into the junction field effect transistor implant layer 40. The well implant layer 50 may comprise a fourth concentration of a second type dopant.

FIG. 3D is a cross sectional view of some of the steps in a method of manufacturing a transistor according to one or more examples. In FIG. 3D, the method may include implanting a source implant layer 60 into the junction field effect transistor implant layer 40 and implanting a plurality of first gate implant layers 70 into the junction field effect transistor implant layer 40. The source implant layer 60 may comprise a fifth concentration of the first type dopant. The plurality of first gate implant layers 70 may comprise a sixth concentration of the second type dopant.

FIG. 3E is a cross sectional view of some of the steps in a method of manufacturing a transistor 10 according to one or more examples. In FIG. 3E, the method may include forming a plurality of first gate contacts 75 operatively connected to the respective first plurality of gate implant layers 70. In FIG. 3E, the method may include forming a source contact 65 operatively connected to the source implant layer 60. In FIG. 3E, the method may include forming a second gate contact 55 operatively connected to the well implant layer 50. The gate contacts 75, 55 may be made from a metal, polysilicon, or other suitable material. The source contact 65 may be made from a metal, polysilicon, or other suitable material. In FIG. 3E, the method may include forming a drain contact 25. The drain contact 25 may be made from a metal, polysilicon, or other suitable material. When a gate-to-source voltage is applied to the transistor 10 (junction field effect transistor) of FIG. 3E, current flows through a channel created around the well implant layer 50 from the source contact 65 to the drain contact 25.

The example method of manufacturing transistor 10 of FIGS. 3A-3E may have the first type dopant be an n-type dopant with the second type dopant being a p-type dopant. Alternatively, the first type dopant may be a p-type dopant with the second type dopant being an n-type dopant.

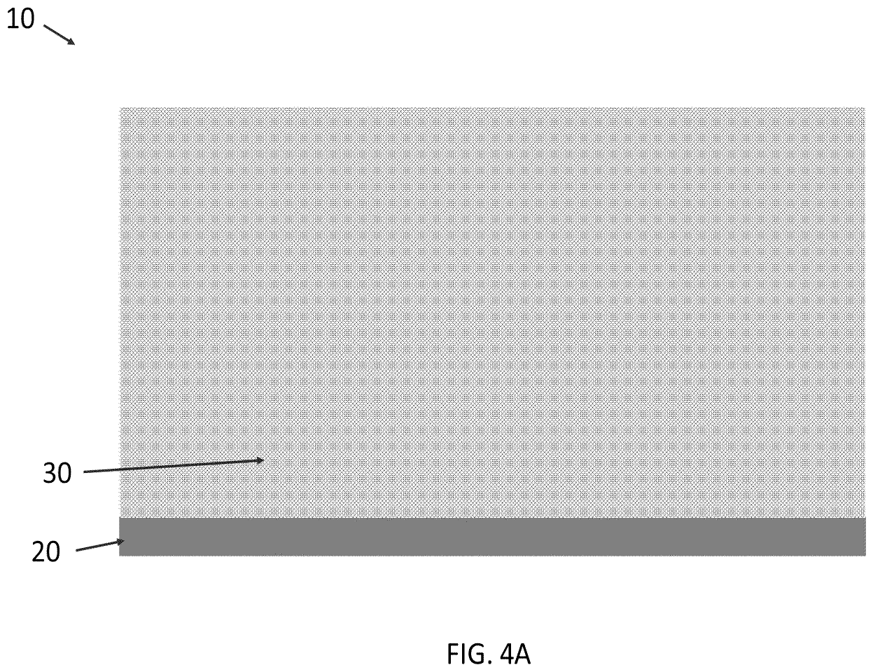

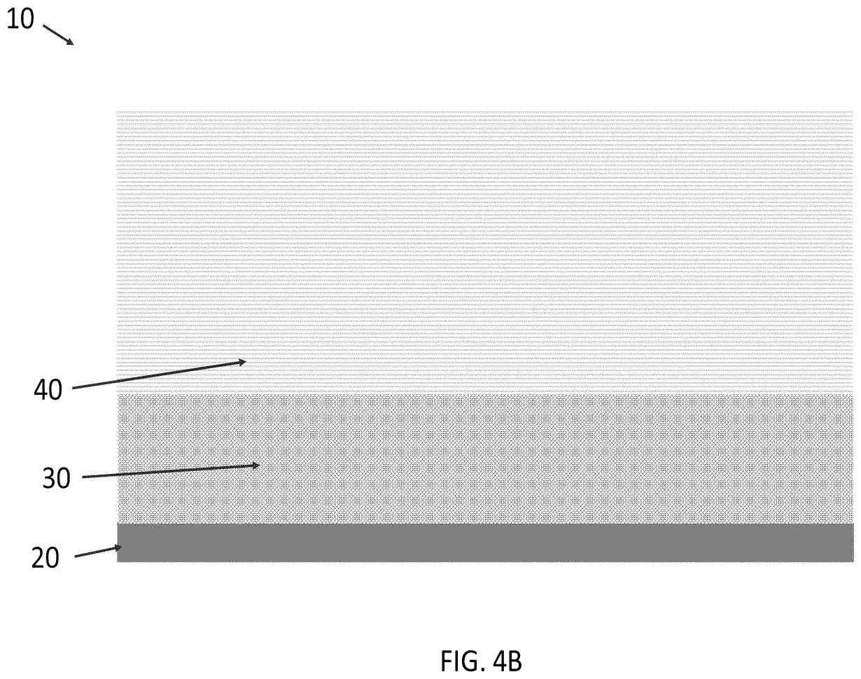

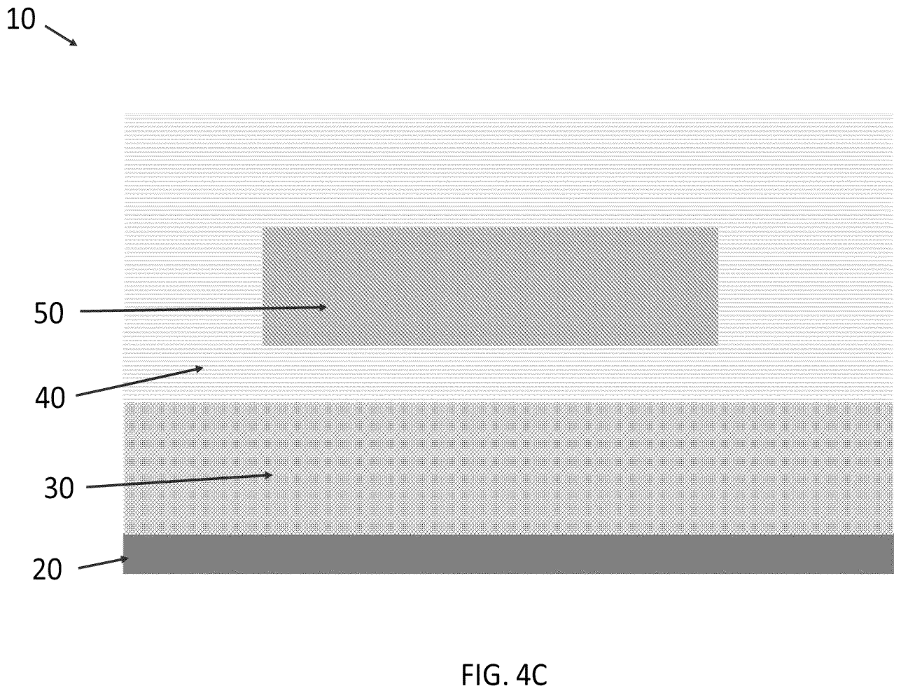

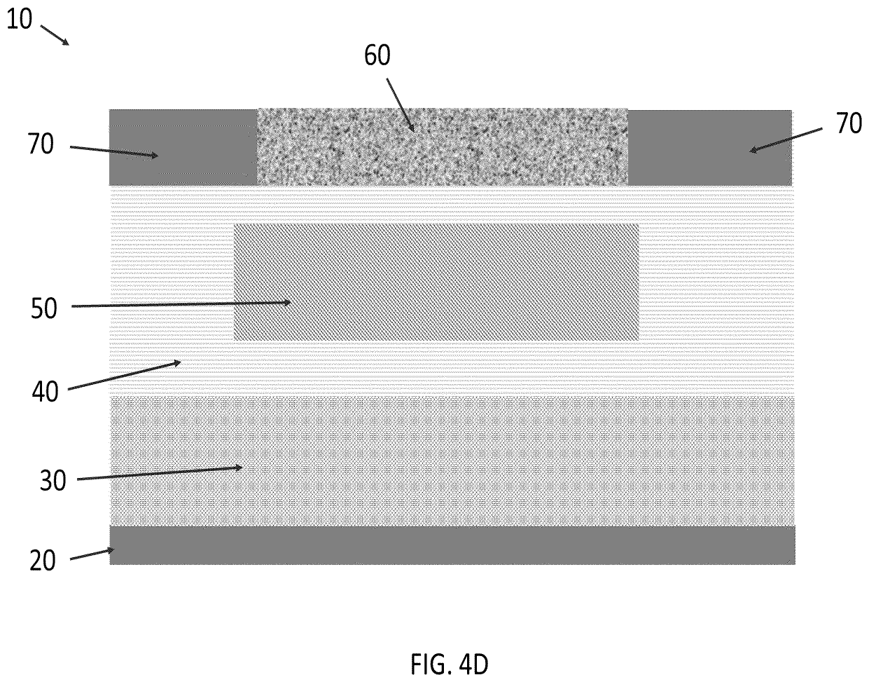

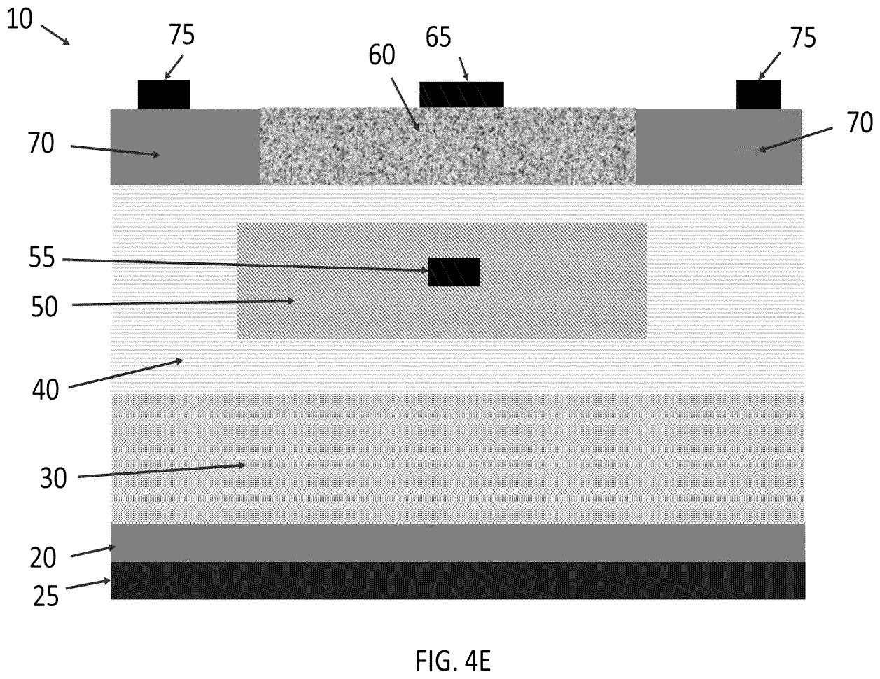

FIGS. 4A-4E show a method of manufacturing transistor 10 according to one or more examples. Although the example method shown in FIGS. 4A-4E include steps shown in a particular order, the steps may be performed in a different order, and may include additional steps that are not explicitly shown.

FIG. 4A is a cross sectional view of some of the steps in a method of manufacturing a transistor 10 according to one or more examples. Transistor 10 may represent, and may be called a junction field effect transistor, without limitation. In FIG. 4A, the example method shows a substrate 20 that may have a first concentration of a first type dopant, e.g., 5E18 (i.e. 5×10¹⁸). In FIG. 4A, the method may include forming an epi layer 30 within the substrate 20. The epi layer 30 may comprise a second concentration of the first type dopant, wherein the first concentration of first type dopant in the substrate 20 may be greater than the second concentration of first type dopant in the epi layer 30.

FIG. 4B is a cross sectional view of some of the steps in a method of manufacturing a transistor 10 according to one or more examples. In FIG. 4B, the method may include implanting a junction field effect transistor layer 40 into the epi layer 30. The junction field effect transistor layer 40 may comprise a third concentration of the first type dopant.

FIG. 4C is a cross sectional view of some of the steps in a method of manufacturing a transistor 10 according to one or more examples. In FIG. 4C, the method may include implanting a well implant layer 50 into the junction field effect transistor implant layer 40. The well implant layer 50 may comprise a fourth concentration of a second type dopant.

FIG. 4D is a cross sectional view of some of the steps in a method of manufacturing a transistor 10 according to one or more examples. In FIG. 4D, the method may include implanting a source implant layer 60 into the junction field effect transistor implant layer 40 and implanting a plurality of first gate implant layers 70 into the junction field effect transistor implant layer 40. The source implant layer 60 may comprise a fifth concentration of the first type dopant. The plurality of first gate implant layers 70 may comprise a sixth concentration of the second type dopant. In FIG. 4D, the plurality of first gate implant layers 70 may be operatively connected to the source implant layer 60.

FIG. 4E is a cross sectional view of some of the steps in a method of manufacturing a transistor 10 according to one or more examples. In FIG. 4E, the method may include forming a plurality of first gate contacts 75 operatively connected to the respective plurality of first gate implant layers 70. In FIG. 4E, the method may include forming a source contact 65 operatively connected to the source implant layer 60. In FIG. 4E, the method may include forming a second gate contact 55 operatively connected to the well implant layer 50. The gate contacts 75, 55 may be made from a metal, polysilicon, or other suitable material. The source contact 65 may be made from a metal, polysilicon, or other suitable material. In FIG. 4E, the plurality of first gate contacts 75 may be operatively connected to the source contact 65. In FIG. 4E, the method may include forming a drain contact 25. The drain contact 25 may be made from a metal, polysilicon, or other suitable material. When a gate-to-source voltage is applied to the transistor (junction field effect transistor) of FIG. 4E, current flows through a channel created around the well implant layer 50 from the source contact 65 to the drain contact 25.

The example method of manufacturing transistor 10 of FIGS. 4A-4E may have the first type dopant be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a substrate;
an epi layer formed within the substrate;
a junction field-effect transistor implant layer formed into the epi layer;
a well implant layer formed within the junction field-effect transistor implant layer;
a source implant layer formed into the junction field-effect transistor implant layer;
a plurality of first gate implant layers formed into the junction field-effect transistor implant layer;
a plurality of first gate contacts operatively connected to the respective first gate implant layer;
a source contact operatively connected to the source implant layer; and
a second gate contact operatively connected to the well implant layer.

2. The transistor of claim 1, wherein the plurality of first gate implant layers operatively connect to the source implant layer and the plurality of first gate contacts operatively connect to the source contact.

3. The transistor of claim 1, wherein the substrate comprises a first concentration of a first type dopant.

4. The transistor of claim 3, wherein the epi layer comprises a second concentration of the first type dopant, the first concentration is greater than the second concentration.

5. The transistor of claim 4, wherein the junction field-effect transistor layer comprises a third concentration of the first type dopant.

6. The transistor of claim 5, wherein the well implant layer comprises a fourth concentration of a second type dopant.

7. The transistor of claim 6, wherein the source implant layer comprises a fifth concentration of the first type dopant.

8. The transistor of claim 7, wherein the plurality of first gate implant layers comprises a sixth concentration of the second type dopant.

9. The transistor of claim 8, wherein the first type dopant comprises an n-type dopant and the second type dopant comprises a p-type dopant.

10. The transistor of claim 8, wherein the first type dopant comprises a p-type dopant and the second type dopant comprises an n-type dopant.

11. A method of manufacturing a transistor, the method comprising:
providing a substrate;
forming an epi layer within the substrate;
implanting a junction field-effect transistor implant layer into the epi layer;
implanting a well implant layer into the junction field-effect transistor implant layer;
implanting a source implant layer into the junction field-effect transistor implant layer;
implanting a plurality of first gate implant layers into the junction field-effect transistor implant layer;
forming a plurality of first gate contacts operatively connected to the respective first gate implant layer;
forming a source contact operatively connected to the source implant layer; and
forming a second gate contact operatively connected to the well implant layer.

12. The method of claim 11, wherein the plurality of first gate implant layers operatively connect to the source implant layer and the plurality of first gate contacts operatively connect to the source contact.

13. The method of claim 11, wherein the substrate comprises a first concentration of a first type dopant.

14. The method of claim 13, wherein the epi layer comprises a second concentration of the first type dopant, the first concentration is greater than the second concentration.

15. The method of claim 14, wherein the junction field-effect transistor layer comprises a third concentration of the first type dopant.

16. The method of claim 15, wherein the well implant layer comprises a fourth concentration of a second type dopant.

17. The method of claim 16, wherein the source implant layer comprises a fifth concentration of the first type dopant.

18. The method of claim 17, wherein the plurality of first gate implant layers comprises a sixth concentration of the second type dopant.

19. The method of claim 18, wherein the first type dopant comprises an n-type dopant and the second type dopant comprises a p-type dopant.

20. The method of claim 18, wherein the first type dopant comprises a p-type dopant and the second type dopant comprises an n-type dopant.
